(19) United States
(12) Patent Application Publication
(10) Pub. No.: US 2019/0382225 A1
(43) Pub. Date: Dec. 19, 2019

(54) DEVELOPING MACHINE AND TRANSMISSION DEVICE THEREOF

(71) Applicant: Wuhan China Star Optoelectronics Technology Co., Ltd, Wuhan, Hubei (CN)

(72) Inventors: Pengbo QI, Wuhan, Hubei (CN); Yekai CHEN, Wuhan, Hubei (CN)

(21) Appl. No.: 15/740,753

(22) PCT Filed: Nov. 29, 2017
(86) PCT No.: PCT/CN2017/113527

§ 371 Date: Dec. 28, 2017

(30) Foreign Application Priority Data
Oct. 25, 2017 (CN) 201711009366.5

(51) Int. Cl. B65H 5/06; H01L 21/677; B65H 27/00; B65H 3/06

(52) U.S. Cl. CPC B65H 5/06; B65H 3/06; B65H 27/00; H01L 21/67706

(57) ABSTRACT

A transmission device of a developing machine is disclosed. The transmission device includes a plurality of transmission units with bearing points thereof arranged on an identical surface to form a bearing surface for transmitting a substrate, and each of the plurality of transmission units comprises a supporting rotating axle and a roller connected with the supporting rotating axle, and the supporting rotating axle has a central rotating axis. A developing machine is also disclosed.

### RELATED APPLICATIONS

The present application is a National Phase of International Application Number PCT/CN2017/113527, filed Nov. 29, 2017, and claims the priority of China Application 201711009366.5, filed Oct. 25, 2017.

### FIELD OF THE DISCLOSURE

The disclosure relates to a display panel technical field, and more particularly to a developing machine and a transmission device thereof.

### BACKGROUND

During thin film transistors (TFTs) are exposed and produced, a glass substrate is cleaned and coated with a photoresistance. Then, the glass substrate is dried at a low pressure and treated during a soft baking process. The glass substrate is placed in an exposing machine. A mask is used to define a pattern of the photoresistance on the glass substrate. Next, the pattern is developed after a developing process. Finally, the glass substrate is treated during a hard baking process to shape the pattern.

In the conventional technology, a developing process is performed after the photoresistance is coated and exposed. The exposed photoresistance is removed, and the unexposed photoresistance remains on the substrate to form the pattern required. When TFTs are developed, a developer nozzle fixed above a platform ejects a developing solution. A transmission device transmits a substrate to pass through under the developer nozzle. The developing solution ejected by the developer nozzle covers the substrate. The photoresistance on the substrate is immersed in the developing solution to achieve the developing purpose.

The design of the transmission device of the conventional developing machine is unreasonable. The drawbacks are described as follows. When the developer nozzle ejects the developing solution, the developing solution easily forms a water film between the developer nozzle and the beam of the transmission device thereunder due to the tension of the solution surface. When the substrate passes through under the developer nozzle, the water film easily covers the substrate. When the air between the substrate and the water film is not smooth expelled, developer bubbles are easily formed on the substrate such that the photoresistance becomes bubbles and the photoresistance is not uniformly developed. Thus, a quantity of the photoresistance remains.

### SUMMARY

A technical problem to be solved by the disclosure is to provide a developing machine and a transmission device thereof, which reduces a contact area between a developer nozzle and transmission units thereunder and reduces the probability of forming a water film to overcome the non-uniformly developing problem.

An objective of the disclosure is achieved by following embodiments. In particular, a transmission device of a developing machine is provided. The transmission device comprises: a plurality of transmission units with bearing points thereof arranged on an identical surface to form a bearing surface for transmitting a substrate, and each of the plurality of transmission units comprises a supporting rotating axle and a roller connected with the supporting rotating axle, and the supporting rotating axle has a central rotating axis.

In an embodiment of the present invention, one of the plurality of transmission units independently drives the roller corresponded thereof.

In an embodiment of the present invention, the plurality of transmission units is arranged into a plurality of columns, and the central rotating axes of the plurality of transmission units of one of the plurality of columns are aligned in the same straight line.

In an embodiment of the present invention, the plurality of columns of the plurality of transmission units are spaced at uniform intervals.

In an embodiment of the present invention, one of the plurality of columns of the plurality of transmission units are uniformly arranged.

In an embodiment of the present invention, at least one of the plurality of columns of the plurality of transmission units is disposed directly under a developer nozzle.

In an embodiment of the present invention, the developer nozzle is 0.3 mm from the central rotating axis of thee plurality of transmission units disposed thereunder the developer nozzle.

In an embodiment of the present invention, the cross-section of the supporting rotating axle has a shape of n.

In order to overcome the abovementioned problem, the present invention also provides a transmission device of a developing machine, which comprises: a plurality of transmission units with bearing points thereof arranged on an identical surface to form a bearing surface for transmitting a substrate, and each of the plurality of transmission units comprises a supporting rotating axle and a roller connected with the supporting rotating axle, and the supporting rotating axle has a central rotating axis, and one of the plurality of transmission units independently drives the roller corresponded thereof, and the plurality of transmission units are arranged into a plurality of columns, and the central rotating axes of the plurality of transmission units of one of the plurality of columns are aligned in the same straight line.

In an embodiment of the present invention, the plurality of columns of the plurality of transmission units is spaced at uniform intervals.

In an embodiment of the present invention, one of the plurality of columns of the plurality of transmission units is uniformly arranged.

In an embodiment of the present invention, at least one of the plurality of columns of the plurality of transmission units is arranged directly under a developer nozzle.

In an embodiment of the present invention, the developer nozzle is 0.3 mm from the central rotating axis of the at least one of the plurality of columns of the plurality of transmission units arranged directly under the developer nozzle.

In an embodiment of the present invention, the cross-section of the supporting rotating axle has a shape of n.

In order to overcome the abovementioned problem, the present invention also provides a developing machine comprising the transmission device of the developing machine.

The developing machine and the transmission device thereof of the present invention have advantages described as follows. The transmission device of the developing machine comprises: a plurality of transmission units with bearing points thereof arranged on an identical surface to form a bearing surface for transmitting a substrate, and each of the plurality of transmission units comprises a supporting rotating axle and a roller connected with the supporting rotating axle, and the supporting rotating axle has a central rotating axis. One of the plurality of transmission units independently drives the roller corresponded thereof. Thus, there is no additional transmission member between transmission units, so as to reduce a contact area between a developer nozzle and transmission units thereunder and reduce the probability of forming a water film to overcome the non-uniformly developing problem.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a schematic view of a transmission unit of a transmission device of a developing machine according to an embodiment of the disclosure; and

FIG. 2 is a cross-sectional schematic view of a transmission device of a developing machine according to an embodiment of the disclosure.

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

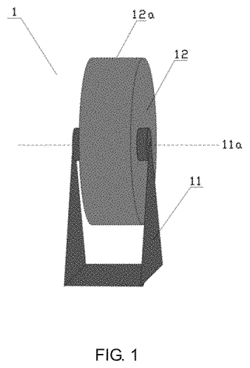

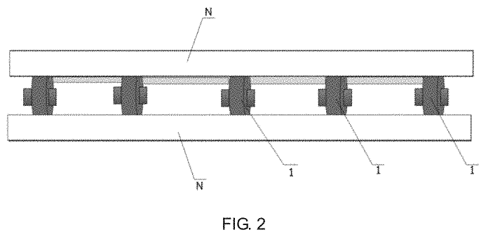

Refer to FIG. 1 and FIG. 2. The first embodiment of he transmission device of a developing machine is introduced.

The transmission device of the developing machine comprises a plurality of transmission units 1 with bearing points 12a thereof arranged on an identical surface to form a bearing surface for transmitting a substrate. The plurality of transmission units 1 is arranged into a plurality of columns.

Specifically, the transmission device comprises a plurality of columns each consisting of a plurality of transmission units 1 uniformly arranged. In other embodiments, the present invention should not be limited to the number of the columns of the transmission device and the number of the transmission units 1 arranged in each column. The neighboring transmission units 1 arranged in each column are spaced at uniform intervals or at non-uniform intervals. Certainly, the plurality of transmission units 1 uniformly arranged can help the transmission device provide uniform bearing force.

In the embodiment, the plurality of columns of the plurality of transmission units is spaced at uniform intervals, as shown in FIG. 2. FIG. 2 shows five transmission units 1. One of the plurality of transmission units 1 independently drives to save transmission members between the transmission units.

Furthermore, the transmission unit 1 comprises a supporting rotating axle 11 and a roller 12 connected with the supporting rotating axle 11, and the supporting rotating axle 11 has a central rotating axis 11a. The top of the roller 12 is used as the bearing point 12a of the transmission unit 1. For such a structural arrangement, one of the plurality of transmission units 1 independently drives the roller 12 corresponded thereof.

Preferably, the cross-section of the supporting rotating axle 11 has a shape of n to reduce its volume, thereby reducing a contact area between a developer nozzle and the transmission unit independently driven.

Furthermore, at least one of the plurality of columns of the plurality of transmission units 1 is arranged directly under a developer nozzle N. In the embodiment, the developer nozzle N is 0.3 mm from the central rotating axis 11a of the transmission units 1 arranged directly under the developer nozzle N.

In the embodiment, the central rotating axes 11a of one of the plurality of columns of the plurality of transmission units are aligned in the same straight line. The transmission unit 1 does not touch its neighboring transmission unit to guarantee that the bearing points 12a of the plurality of transmission units 1 are arranged on an identical surface to form a bearing surface for transmitting a substrate. In other embodiments, when the diameters of the rollers 12 of the transmission units 1 arranged in the same column are different, the height of the supporting axle 11 is adjusted to change the position of the central axis 11a, such that the bearing points 12a of the plurality of transmission units 1 are arranged on the same surface. In this way, the transmission device is more flexibly arranged.

Each transmission unit 1 independently drives the roller corresponded thereof. Accordingly, without affecting the effect that the transmission device transmits the substrate, there is no additional transmission member between transmission units 1, so as to reduce a contact area between a developer nozzle and transmission units thereunder and reduce the probability of forming a water film to overcome the non-uniformly developing problem.

Moreover, the present invention discloses a developing machine comprising the transmission device of the developing machine. The embodiment of the developing machine is the same to that of the transmission device of the developing machine so will not be reiterated.

The developing machine and the transmission device thereof of the present invention have advantages described as follows. The transmission device of the developing machine comprises: a plurality of transmission units with bearing points thereof arranged on an identical surface to form a bearing surface for transmitting a substrate, and each of the plurality of transmission units comprises a supporting rotating axle and a roller connected with the supporting rotating axle, and the supporting rotating axle has a central rotating axis. One of the plurality of transmission units independently drives the roller corresponded thereof. Thus, there is no additional transmission member between transmission units, so as to reduce a contact area between a developer nozzle and transmission units thereunder and reduce the probability of forming a water film to overcome the non-uniformly developing problem.

The foregoing contents are detailed description of the disclosure in conjunction with specific preferred embodiments and concrete embodiments of the disclosure are not limited to these description. For the person skilled in the art of the disclosure, without departing from the concept of the disclosure, simple deductions or substitutions can be made and should be included in the protection scope of the application.

What is claimed is:

1. A transmission device of a developing machine comprising:
a plurality of transmission units with bearing points thereof arranged on an identical surface to form a bearing surface for transmitting a substrate, and each of the plurality of transmission units comprising a supporting rotating axle and a roller connected with the supporting rotating axle, and the supporting rotating axle has a central rotating axis.

2. The transmission device of the developing machine according to claim 1, wherein one of the plurality of transmission units independently drives the roller corresponded thereof.

3. The transmission device of the developing machine according to claim 1, wherein the plurality of transmission units are arranged into a plurality of columns, and the central rotating axis of the plurality transmission units of any one of the plurality of columns are aligned in a same straight line.

4. The transmission device of the developing machine according to claim 2, wherein the plurality of transmission units are arranged into a plurality of columns, and a central rotating axes of the plurality transmission units of any one of the plurality of columns are aligned in a same straight line.

5. The transmission device of the developing machine according to claim 3, wherein the plurality of columns of the plurality of transmission units are spaced at uniform intervals.

6. The transmission device of the developing machine according to claim 3, wherein the plurality of transmission units of any one of the plurality of columns are uniformly arranged.

7. The transmission device of the developing machine according to claim 3, wherein at least one of the plurality of columns arranged by the plurality of transmission units is disposed directly under a developer nozzle.

8. The transmission device of the developing machine according to claim 7, wherein the developer nozzle is 0.3 mm from the central rotating axis of the plurality of transmission units disposed thereunder.

9. The transmission device of the developing machine according to claim 1, wherein a cross-section of the supporting rotating axle has a shape of n.

10. A transmission device of a developing machine comprising:
a plurality of transmission units with bearing points thereof arranged on an identical surface to form a bearing surface for transmitting a substrate, and each of the plurality of transmission units comprising a supporting rotating axle and a roller connected with the supporting rotating axle, and the supporting rotating axle has a central rotating axis, and one of the plurality of transmission units independently drives the roller corresponded thereof, and the plurality of transmission units is arranged into a plurality of columns, and a central rotating axes of the plurality transmission units of any one of the plurality of columns are aligned in a same straight line.

11. The transmission device of the developing machine according to claim 10, wherein the plurality of columns of the plurality of transmission units is spaced at uniform intervals.

12. The transmission device of the developing machine according to claim 10, wherein one of the plurality of columns of the plurality of transmission units is uniformly arranged.

13. The transmission device of the developing machine according to claim 10, wherein at least one of the plurality of columns arranged by the plurality of transmission units is disposed directly under a developer nozzle.

14. The transmission device of the developing machine according to claim 13, wherein the developer nozzle is 0.3 mm from the central rotating axis of the plurality of transmission units of the at least one of the plurality of columns arranged directly under the developer nozzle.

15. The transmission device of the developing machine according to claim 10, wherein a cross-section of the supporting rotating axle has a shape of n.

16. A developing machine comprising the transmission device of the developing machine of claim 10.
